(19) United States
(12) Patent Application Publication
(10) Pub. No.: US 2024/0413000 A1
(43) Pub. Date: Dec. 12, 2024

(54) Aluminum Nitride Assemblage

(71) Applicant: Morgan Advanced Ceramics, Inc., Hayward, CA (US)

(72) Inventors: Chengtsin Lee, Hayward, CA (US); David Carloni, Hayward, CA (US)

(73) Assignee: Morgan Advanced Ceramics, Inc., Hayward, CA (US)

(21) Appl. No.: 18/697,534

(22) PCT Filed: Sep. 20, 2022
(86) PCT No.: PCT/US2022/044069

§ 371 Date: Apr. 1, 2024

Related U.S. Application Data
(60) Provisional application No. 63/251,145, filed on Oct. 1, 2021.

(30) Foreign Application Priority Data
Nov. 22, 2021 (GB) 2116818.2

(51) Int. Cl. H01L 21/683; C03C 10/00; C04B 35/581; C04B 37/00

(52) U.S. Cl. CPC H01L 21/6833; C03C 10/00; C04B 35/581; C04B 37/005; C03C 2201/3411; C04B 2235/3865; C04B 2237/066; C04B 2237/10; C04B 2237/366

(57) ABSTRACT

This invention relates to an assemblage of a semiconductor processing apparatus comprising a first aluminum nitride (AlN) component and a second aluminum nitride component, wherein the first and second aluminum nitride components are connected by a joint, said joint comprising a composite glass-ceramic comprising Y₂O₃—Al₂O₃—SiO₂ (YAS) glass; and at least one of crystalline aluminosilicate and aluminum nitride.

### FIELD OF THE INVENTION

The present invention relates to aluminum nitride assemblages comprising a glass ceramic joint, mainly for use in semi-conductor processing equipment, such as electrostatic chucks and heaters. In particular, the present invention relates to the bonding of a pedestal to an electrostatic chuck or heater.

### BACKGROUND

Semiconductor processing techniques, such as etching, chemical vapor deposition, and ion implant typically require exposure of processing equipment to corrosive gases, such as fluorine and chlorine, in a sealed chamber environment. In such processes, an electrostatic chuck may be used to hold and support a semiconductor wafer within the chamber. The chamber gases corrode the exposed metallic leads that supply power to the embedded electrodes of the electrostatic chuck. A pedestal, consisting of a cylindrical shaft joined to the electrostatic chuck/heater, may be utilized to safely remove and transport the electrostatic chuck and semiconductor wafer from the process chamber while simultaneously housing and protecting metallic leads from corrosion during processing.

Joining such a pedestal to the electrostatic chuck/heater in a manner which is sufficient for use in a semiconductor processing chamber while preserving the properties and performance of the component subassemblies is a challenging feat. For example, US2013/0319762 discloses the use of a slurry containing rare-earth oxide transient liquid-phase sintering additives applied at the joint interface to directly bond aluminum nitride ceramics via co-firing at a high temperature. Although this technique yields a hermetic joint which resembles that of a monolithic part, geometrical flatness maintenance is difficult to achieve when co-firing ceramics. In another example, WO 2009/010427 discloses the use of a thin composite layer composed of AlN, Al₂O₃, and Y₂O₃ which is hot-pressed at high temperatures and pressures to join pre-sintered ceramics. Re-firing a previously sintered ceramic to high-temperatures and pressures can compromise the pre-existing microstructure, dimensions, and properties, which is disadvantageous for precisely engineered devices, such as an electrostatic chuck.

Additionally, U.S. Pat. No. 6,261,708 discloses the fabrication of a paste containing a CaO—Y₂O₃—Al₂O₃ flux and AlN aggregate to join AlN ceramics through a two-step and relatively low-temperature firing profile at high-pressure. Although this approach utilizes slightly lower process temperatures than the previous examples while maintain good joint properties, the use of extensive processing steps in the preparation of the joining paste and subsequent long firing profile and high pressures can incur significant additional costs to the overall manufacturing process and potentially hinder the properties and performance of the base materials. Further, the use of dissimilar materials which may not match with the coefficient of thermal expansion of aluminum nitride or wet the grain boundaries of the sintered aluminum nitride ceramic may result in poor bonding performance during use.

Accordingly, there is a need for an aluminum nitride assemblage which ameliorates at least some of the abovementioned limitations.

### SUMMARY OF THE INVENTION

In a first aspect of the present disclosure, there is provided an assemblage of, or for, a semiconductor processing apparatus comprising a first aluminum nitride (AlN) component and a second aluminum nitride component, wherein the first and second aluminum nitride components are connected by a joint, said joint comprising a composite comprising:
a) Y₂O₃—Al₂O₃—SiO₂ (YAS) glass;
b) at least one or both of crystalline aluminosilicate and aluminum nitride.

The sum of a)+b) is preferably at least 80 wt % or at least 90 wt % or at least 95 wt % or at least 99 wt % of the total mass of the joint.

The joint material may comprise at least three distinct phases: a YAS glass which enables flow across the joint and liquid-phase diffusion bonding with the AlN ceramic bodies; an in-situ crystalline aluminosilicate phase (e.g. mullite) to improve strength and fracture toughness; and AlN filler particles to restrict overflow of the glass and reduce the differences in the coefficient of thermal expansion across the joint, thereby enhances the joint's thermal shock resistance.

It has been found that the composite glass-ceramic joining material of the present invention forms a dense, strong, and hermetic joint between aluminum nitride ceramics. Furthermore, the method of joining used in the present invention should not significantly alter the properties of the aluminum nitride base material due to the low-temperature and pressure requirements of the joining method.

The crystalline aluminosilicate and/or aluminum nitride, when present, is preferably encompassed within the YAS glass. Crystalline aluminosilicate and optional AlN particles may be dispersed within a YAS glass matrix.

The joint may comprise:
50 to 100 wt % Y₂O₃—Al₂O₃—SiO₂ (YAS) glass;
0 or >0 to 30 wt % crystalline aluminosilicate; and/or
0 or >0 to 50 wt % aluminum nitride.

The sum of Y₂O₃+Al₂O₃+SiO₂ in the YAS glass is preferably at least 90 wt % of at least 95 wt % or at least 98 wt % or at least 99 wt % or at least 99.5 wt %. A high purity is less likely to contaminate the semiconductor manufacturing environment that it may be used in.

The sum of YAS glass+crystalline aluminosilicate+AlN is preferably at least 98 wt % or at least 99 wt % or at least 99.5 wt % of the joint. Preferably, the joint comprises less than 1.0 wt % or less than 0.5 wt % or less than 0.3 wt % or less than 0.2 wt % or less than 0.1 wt % incidental impurities. In some embodiments, the joint is substantially free (e.g. less than 0.10 or less than 0.05 wt %) of volatile impurities (e.g. Cu and/or Na).

The density of the joint is preferably greater than 97%, more preferably greater than 98% and even more preferably greater than 99% of the theoretical maximum density of the ceramic material with a porosity of 0%. Alternatively, the void content of the first ceramic layer is preferably less than 3% v/v, more preferably less than 2% v/v and even more preferably less than 1% v/v. A high theoretical density and/or and low void content results in low gas leakage (good hermeticity) of the joint.

The YAS glass may comprise:
20-70 wt % Y₂O₃;
10-50 wt % Al₂O₃; and
1-50 wt % SiO₂.

In a second aspect of the present invention, there is provided an assemblage of a semiconductor processing apparatus comprising a first aluminum nitride (AlN) component and a second aluminum nitride component, wherein the first and second aluminum nitride components are connected by a joint, said joint comprising a composite glass-ceramic comprising a Y₂O₃—Al₂O₃—SiO₂ (YAS) glass phase comprising:
20-70 wt % Y₂O₃;
10-50 wt % Al₂O₃; and
1-50 wt % SiO₂;
and the sum of Y₂O₃+Al₂O₃+SiO₂ is preferably at least 95 wt %.

In some embodiments, the YAS glass comprises a peripheral region and a core region, said peripheral region interfacing with at least a portion of the first and/or second aluminum nitride components and the core region located in at least the central region of the joint. In some embodiments, the core region spans between a portion of the first and second aluminum nitride components. The first and/or second aluminum nitride components may comprise a glass/amorphous phase derived from a sintering aid used in its formation. The glass/amorphous phase may be a Y₂O₃ rich phase (i.e. Y₂O₃ is the major component or represents at least 30 wt % of the phase).

The peripheral region may comprise a YAS glass composition with an alumina content greater than the YAS glass of the core region. The peripheral region may comprise a YAS glass composition with Y₂O₃ content greater than the YAS glass of the core region. The YAS glass composition of the peripheral region may comprise a Y₂O₃ content lower than the Y₂O₃ rich phase in the first and/or second AlN component. A graduated Y₂O₃ content across the AlN components and the joint is thought to contribute to a more thermally shock resistant joint. The proportion of the peripheral region relative to the core region may be increased through extending the firing time and/or firing temperature. In some embodiments, the proportion of YAS glass in the peripheral region to the core region is in a volume ratio of 1:20 to 1:1 or 1:10 to 1:2.

The presence of two glass phases within the joint enables the co-efficient of thermal expansion to graduate from the AlN components to the core of the joint, thereby enhancing thermal shock resistance.

In some embodiments, the YAS glass composition of the peripheral region comprises:
45-70 wt % or 55-65 wt % Y₂O₃;
20-50 wt % or 30 to 45 wt % Al₂O₃; and
1-20 wt % or 2-10 wt % or 3 to 7 wt % SiO₂.

In some embodiments, the YAS glass composition of the core region comprises:
30-55 wt % Y₂O₃;
10-30 wt % Al₂O₃; and
15-50 wt % SiO₂.

The sum of Y₂O₃+Al₂O₃+SiO₂ in glass composition in the core and/or peripheral region may comprise at least 90 wt % or 95 wt % of the total weight of the glass.

In some embodiments, the joint comprises >0 to 50 wt % AlN or 2 to 30 wt % AlN or 3 to 20 wt % AlN or 4 to 10 wt % AlN. The AlN may be present as discrete particles. The particles may be encompassed by the YAS glass. The AlN particle size distribution may be characterized by an arithmetic average or D₅₀ (on a weight basis) of less than 5 μm or less than 3 μm or less than 1 μm; and at least 100 nm or at least 200 nm or at least 500 nm or at least 800 nm.

In some embodiments, the joint comprises >0 to 30 wt % crystalline aluminosilicate or 1 to 25 wt % or 2 to 24 wt % or 3 to 22 wt % or 5 to 20 wt % crystalline aluminosilicate. In some embodiment, the crystalline aluminosilicate comprises or consists of mullite. The average crystalline aluminosilicate particle size may be less than 20 μm or less than 15 μm or less than 10 μm. The minimum size of the crystalline aluminosilicate particles may be at least 1 μm or at least 3 μm.

In some embodiments, the joint comprises 55 to 95 wt % YAS glass or 60 wt % to 90 wt % YAS glass or 65 wt % to 80 wt % YAS glass or 70 wt % to 78 wt % YAS glass.

The joint thickness is typically no more than 150 μm or no more than 100 μm or no more than 50 μm. For a sufficiently robust joint, a thickness of at least 10 μm or at least 20 μm or at least 30 μm is preferred.

In some embodiments, the assemblage a He leakage rate of no more than 1×10⁻⁵ mbar-l/sec or no more than 1×10⁻⁷ mbar-l/sec determined in accordance with ASTM F19.

The assemblage of the present disclosure may be advantageous applied to a variety of semi-conductor processing apparatus. In some embodiments, the first AlN component is an electrostatic chuck and the second AlN component is a pedestal shaft.

In some embodiments, at least one AlN component comprises a sintering aid, such as Y₂O₃. The presence of a Y₂O₃ in the AlN component (e.g. >0 to 7 wt % or >0 to 5 wt % or at least 1 wt % of at least 2 wt % or at least 3 wt % or at least 4 wt %) is thought to contribute to a strong joint, with a Y₂O₃ phase in the AlN component(s) extending from the AlN component(s) and into the joint, as evidenced in the peripheral region of the YAS glass phase of the joint. It is thought that the Y₂O₃ in the joint material enhances wetting in the AlN component(s) because it blends in with the Y₂O₃ rich grain boundary phase in the AlN component, thereby forming the peripheral region of the YAS glass phase.

In a third aspect of the present disclosure there is provided a process for the formation of an assemblage of a semiconductor processing apparatus of the first aspect of the present disclosure comprising the steps of:
A. applying a paste comprising a solvent and the composite glass ceramic or a precursor thereof to a surface of the first AlN and/or second AlN component;
B. join the surfaces of the first and second AlN component together to form a green assemblage; and
C. firing the green assemblage below the sintering temperature of the first and second AlN components for sufficient time to form the assemblage comprising a He leakage rate of no more than 1×10⁻⁵ mbar-l/sec determined in accordance with ASTM F19.

The firing conditions may be adjusted to control the proportion of the YAS glass peripheral region relative to the YAS glass core region.

The green assemblage may be fired at a temperature in the range of 1400 to 1600° C. for at least 15 minutes. For clarity, “green” assemblage refers to the paste being green or unfired. The AlN components in the assemblage are preferably sintered AlN components. Indeed, the firing conditions, including time, pressure and temperature, of the green assemblage is preferable such that the functional properties or microstructure of the AlN components are not significantly affected. In some embodiments, the green assemblage is fired to a temperature no greater than 1550° C. In some embodiments, the green assemblage is fired at a temperature of no more than 1500° C. In some embodiments, the green assemblage is fired under a non-oxidising atmosphere (e.g. N₂ or H₂).

In some embodiments, the surface or the first and/or second AlN component has a roughness (Rₐ) value of no more than 45 μm.

To enable a mechanical robust joint, the green assemblage is maintained under a load in the range of 100 Pa and 1000 Pa or between 200 Pa and 800 Pa or 300 Pa to 600 Pa. Higher loads may result in the paste being squeezed outside the joint and the joint thickness becoming too thin. Lower loads may result in the paste not forming a continuous bond with the AlN components, resulting in poor hermeticity.

In a fourth aspect of the present disclosure there is provided, a process of manufacturing a semiconductor comprising placing the assemblage as defined in the first aspect of the present disclosure, into a semiconductor processing chamber and exposing the assemblage to a halogen gas containing atmosphere. The halogen gas may comprise or consist of chlorine or fluorine.

In a fifth aspect of the present disclosure, there is provided a paste for use in forming the assemblage as defined in the first aspect of the present disclosure, comprising a composite glass-ceramic or precursor thereof having a composition comprising (on a solvent free basis):
10-60 wt % Y₂O₃;
5-40 wt % Al₂O₃;
10-60 wt % SiO₂; and
0-30 wt % AlN.

In some embodiments, the sum of Y₂O₃+Al₂O₃+SiO₂+AlN is at least 90 wt % or at least 95 wt % or at least 98 wt % or at least 99 wt % of the total weight of the paste on a solvent free basis. In some embodiments, the AlN content is less than 25 wt % or less than 20 wt % of less than 18 wt % or less than 12 wt %. Excessive amounts of AlN particles within the paste may result in the paste being too viscous, at the application temperature, thereby compromising the effectiveness of the paste in evenly distributing across the substrate interface to form a hermetic join.

In some embodiment, the paste comprises particles of AlN. In some embodiments, the paste comprises:
20-40 wt % Y₂O₃;
20-40 wt % Al₂O₃;
20-40 wt % SiO₂; and
1-20 wt % AlN

The paste, when applied under the process of the second aspect of the present disclosure, may produce an assemblage under the first aspect of the present disclosure.

The paste offers the advantage of joining pre-sintered aluminum nitride bodies at a relatively low-temperature and short cycle time in order to retain the microstructure, properties, and geometry of the base aluminum nitride materials. Additionally, the paste has been designed to match the coefficient of thermal expansion of aluminum nitride and possesses desirable etch and corrosion resistance properties, making it suitable for use in semiconductor processing applications.

The paste and method for joining pre-sintered aluminum nitride bodies in the present disclosure utilizes relatively simple and inexpensive processes. Processing steps include dry-pressing or iso-pressing and sintering aluminum nitride bodies, grinding and polishing the joint surfaces, applying the paste to the joint surfaces in slurry form, mating the joint surfaces under a load, and firing at a relatively low-temperature and short cycle. The addition of AlN particles to the paste is thought to help prevent the liquid components of the paste from mitigating from the join during the mating process, thereby promoting a stronger more hermetic joint.

Unless indicated to the contrary, angular dark grains within the joint comprising a high aluminosilicate (e.g. >70 wt % or 80 wt % or 90 wt %) will be deemed to be a crystalline aluminosilicate phase.

### BRIEF DESCRIPTION OF THE FIGURES

FIG. 1 is a process flow diagram according to an exemplary embodiment of the current disclosure.

FIG. 2 is a cross-sectional diagram illustration of an aluminum nitride substrate which has been joined to an aluminum nitride shaft using the composite glass-ceramic joining material according to an exemplary embodiment of the current disclosure.

FIG. 3 is an SEM micrograph showing the microstructure of the composite glass-ceramic joining material disposed between aluminum nitride substrates according to Example 1 of the current disclosure.

FIG. 4 is a magnified SEM micrograph of FIG. 3 highlighting analysis points which are displayed in Table 2.

FIG. 5 is an SEM micrograph showing the microstructure of the joining material according to Example 2 disposed between aluminum nitride substrates.

FIG. 6 is a magnified SEM micrograph of a section of FIG. 5 showing the joint microstructure in more detail.

FIG. 7 is an SEM micrograph showing the microstructure of an alternative joining material according to Comparative Example #1 disposed between aluminum nitride substrates as a comparison to the current disclosure.

FIG. 8 is an SEM micrograph showing the microstructure of another alternative joining material according to Comparative Example #2 disposed between aluminum nitride substrates as a comparison to the current disclosure.

### DETAILED DESCRIPTION OF THE PREFERRED EMBODIMENTS

Representative applications of glass ceramic joints and AlN assemblages comprising the same, and methods according to the presently described embodiments are provided in this section. These examples are being provided solely to add context and aid in the understanding of the described embodiments. It will thus be apparent to one skilled in the art that the presently described embodiments can be practiced without some or all of these specific details. In other instances, well known process steps have not been described in detail in order to avoid unnecessarily obscuring the presently described embodiments. Other applications are possible, such that the following examples should not be taken as limiting.

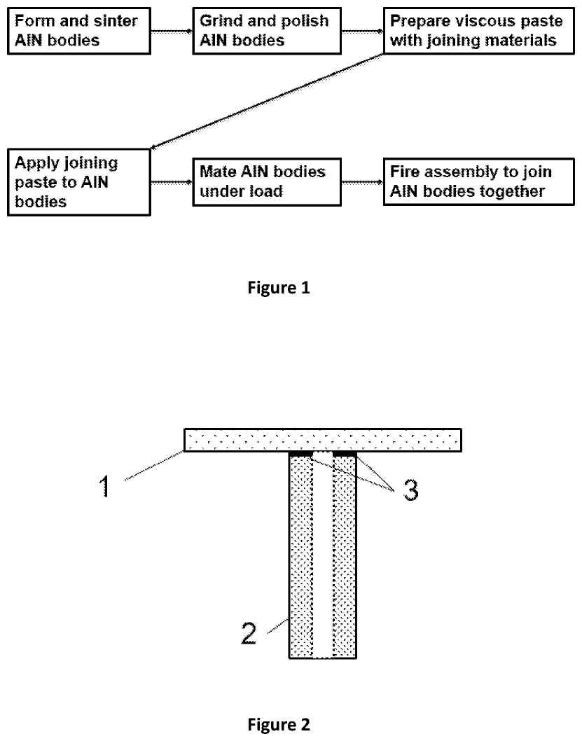

As illustrated in FIG. 1, the process of joining to AlN bodies together involves forming and sintering AlN bodies, followed by surface preparation involving grinding and polishing to obtain a smooth joining surfaces to which a joining paste, which has been prepared as a viscous past of joining materials, is applied. The two AlN bodies are then mated under load and then fired to produce the final assembly.

In reference to FIG. 2, shown is a cross-sectional diagram illustration of a final assembled part as joined according to an exemplary embodiment of the current disclosure. The assembly consists of a sintered AlN substrate 1 and a sintered AlN pedestal shaft 2, which have been joined using the composite glass-ceramic joining material of the present disclosure 3 disposed at the interface between 1 and 2. It is preferred that this assembly is retained in good geometrical constraints. Ideally, the process described in FIG. 1 does not significantly alter the microstructure, function or performances of the component pieces 1, 2.

In one embodiment, green AlN bodies with at least 1 wt % Y₂O₃ sintering aid are preferably formed into the desired shapes through dry-pressing or iso-pressing, such as the substrate and pedestal shaft of FIG. 2. The formed green AlN components are debinded using a slow and controlled ramp rate not greater than 2° C./min to 375° C. and held for at least 1 hr, followed by a slow controlled cool to room-temperature at a rate not greater than 4° C./min. The debinded AlN ceramics are then sintered using a ramp rate of no faster than 15° C./min to 1850° C., held at 1850° C. for at least 1 hr, and then cooled back down to room temperature at a rate not greater than 15° C./min. It is preferred that the sintered AlN components possess a density of at least 3.30 g/cm³ measured via the Archimedes method and a uniform microstructure with an average grain size not greater than 20 μm. The sintered AlN ceramics are then ground and polished at their respective joining surfaces to achieve a flat and smooth interface for joining. It is preferred that the surface roughness (Rₐ) is no greater than 45 μm.

A paste containing components of the composite glass-ceramic joining materials is prepared to be applied at the joining interface. Raw powder materials of the joining material are preferably mixed in the following proportions: 50-100% of a Y₂O₃—Al₂O₃—SiO₂ (YAS) glass forming component and 0-50 wt % of aluminum nitride raw powder. Wherein the YAS glass forming component contains 10-60 wt % Y₂O₃, 5-40 wt % Al₂O₃, and 10-60 wt % SiO₂. Paste compositions within this range have a relatively low melting point and are able to generate crystalline aluminosilicate phases, such as mullite.

It is preferred that the raw powder materials used are of high purity (e.g. greater than 98 wt % or greater than 99 wt % or greater than 99.5 wt % purity). The component powder joining materials are then mixed and milled with a binder and solvent to form a viscous paste. It is preferred that the joining material paste exhibits a viscosity suitable for screen-printing applications with a solids-loading of at least 50 wt %, with the paste fully homogenized through thorough mixing of the components. The prepared paste is then applied to the joining surface of each sintered AlN body in a thin and uniform layer. Preferably the paste is applied using the screen-printing method at a thickness of less than 0.005″ (127 μm).

The sintered AlN bodies with the joining paste applied at their joining surfaces are then mated surface-to-surface and fired in N₂ atmosphere to form a solid joint. It is preferred that a load is applied perpendicular to the joining interface during the firing process to force contact between the joined faces and promote flow and uniform distribution of the glass phase along the joint. It is preferred that the assembly be fired to a peak temperature between 1450° C.-1550° C. with a dwell time between 5 mins-2 hrs. It is further preferred that the heating and cooling rates during firing are between 10-30° C./min.

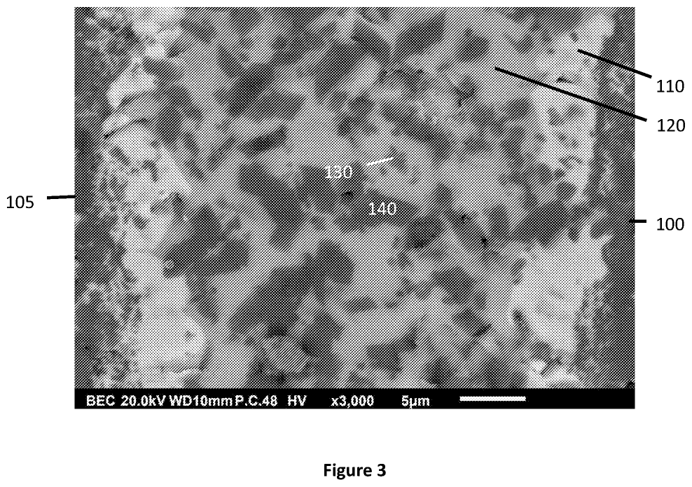

As seen in the SEM micrograph FIG. 3, which is a cross-section of the joint region of joined AlN ceramics prepared according to this preferred embodiment, the sintered AlN substrates 100, 105 have been joined between the composite glass-ceramic joining material, which comprises AlN particles 130 and mullite particles 140 embedded within a YAS glass matrix 110, 120. The YAS glass matrix comprises a lighter colored peripheral region 110 and a darker colored core region 120. The microstructure shows a thin, uniform, and continuous joint layer which is free of voids and defects. Additionally, the backscattered image enables the identification of a continuous yttria aluminosilicate glass-phase with a homogeneously distributed aluminosilicate (mullite) crystals and AlN filler particles.

### Examples

Experiments were conducted to quantify the strength and hermeticity of AlN ceramics joined using the glass-ceramic composite joining material of the current disclosure as well as other joining materials which may be used in the semiconductor field as comparative examples using the ASTM F19 standardized procedure. AlN spray-dried powder containing 4 wt % Y₂O₃ sintering aid was used as the base powder material. AlN iso-pressed cylinders were formed, machined to the ASTM F19 sample specifications, and debinded at 375° C. for 2 hrs with a ramp and cool rate of 1.5° C./min and 3° C./min, respectively. The debinded ceramics were then sintered to 1850° C. for 3 hrs with a ramp and cool rate of 10° C./min to achieve a density of at least 3.30 g/cm³. The surfaces to be joined were then ground to flat and polished incrementally with a polishing wheel and diamond slurry up to a Roughness, Ra, of 9 μm.

Joining pastes of varying compositions were prepared of approximately 65-70 wt % solids with remainder of binder and solvent to yield a viscous and screen-printable paste. For the composite glass-ceramic joining materials of the present disclosure, from hereafter referred to as:
“YAS+10% AlN” (Example 1), the solids content of the paste was composed of 30 wt % Y₂O₃, 30 wt % Al₂O₃, 30 wt % SiO₂, and 10 wt % AlN;
YAS (1:1:1) (Example 2) the solids content of the paste was composed of 30 parts by weight (pbw) Y₂O₃, 30 pbw Al₂O₃, 30 pbw SiO₂; and
YAS (9:2:9) (Example 3) the solids content of the paste was composed of 9 pbw Y₂O₃, 2 pbw Al₂O₃, 9 pbw SiO₂.

Example 2 differs from Example 1, in that sample contains no AlN (i.e. only the Y₂O₃, Al₂O₃ and SiO₂ in a weight ratio of 1:1:1, such ratio being effective to yield crystalline aluminosilicate phases upon formation of the joint). Example 3, differed from Example 2, in that the weight ratio of Y₂O₃, Al₂O₃ and SiO₂ was adjusted to 9:2:9, such that the no crystalline aluminosilicate phases were formed.

As an alternative joining solution, from hereafter referred to as “Comparative Example #1” (CE #1), the solids content of the paste was composed of 40 wt % AlN, 15 wt % Al₂O₃, 8 wt % Y₂O₃, and 37 wt % CaCO₃. As another alternative joining solution, from hereafter referred to as “Comparative Example #2” (CE #2), the solids content of the paste was composed of 70 wt % AlN, 15 wt % Al₂O₃, and 15 wt % Y₂O₃.

Each joining paste was applied in a thin layer of approximately 0.003″ (≈76 μm) thickness to the joining surface of each respective AlN ASTM F19 part. The parts were then mated under an approximately 5 g load and fired under varying profiles depending on their composition. The samples (1 to 3) were fired at 1500° C. in N₂ atmosphere for a 30 min dwell with a 10° C./min ramp and cool rate. For Comparative Example #1, the samples were fired in N₂ atmosphere with a ramp rate of 10° C./min to 1400° C. for 2 hrs, followed by a second ramp at 10° C./min up to 1600° C. for another 2 hr dwell, and finally a 10° C./min cool to room-temperature. For Comparative Example #2, samples were fired in N₂ atmosphere at 10° C./min to 1850° C. for a 1 hr dwell, followed by a 10° C./min cool to room-temperature.

The joined parts were then tested under the ASTM F19 standard procedure for hermeticity using a He spectrometer and for tensile strength using an Instron. The ASTM F19 testing results for each joining material of the present disclosure are shown in Table 1.

As indicated in Table 1, Example 1 achieved the combination of highest average strength at 23.6±4.6 MPa and lowest He leakage rate in the range of 1×10⁻⁸-1×10⁻⁹ mbar-l/sec (1×10⁻⁹-1×10⁻¹⁰ KPa-l/sec) across 5 samples. While Example 2, achieved a similar joint strength to Example 1, it had a reduced hermeticity performance. While Example 3, achieved a similar joint hermeticity performance to Example 1, it had a reduced joint strength. Comparative Example #1 (CE #1) achieved an average strength of only 10.8±3.9 MPa and a He leakage rate in the range of about 1×10⁻³-1×10⁻⁴ mbar-l/sec (1×10⁻⁴-1×10⁻⁵ KPa-l/sec) across 5 samples. Finally, the worst performing joining material was Comparative Example #2 (CE #2), which achieved an average strength of only 6.3±1.9 MPa and He leakage rate in the range of about 1×10⁻¹-1×10⁻¹ mbar-l/sec (1×10⁻²-1×10⁻³ KPa-l/sec) across 3 samples. This data suggests that the Example 1 (YAS+10%) AlN joining solution, followed by Examples 2 & 3, of the present disclosure possesses improved strength and hermeticity values when compared to other potential joining solutions of different compositions and joining conditions.

TABLE 1

| | Joining | Average | | |
|---|---|---|---|---|
| | Temp. | Strength | Hermeticity | Sample |
| Joint material | (° C.) | (MPa) | (mbar · l/sec) | size |
| 1 | 1500 | 23.6 ± 4.6^{&} | 1 × 10⁻⁸ to 1 × | 5 |
| YAS (1:1:1) + | | | 10⁻⁹ | |
| 10% AlN | | | | |
| 2 | 1500 | 23.8 ± 2.3 | 1 × 10⁻⁵ to 1 × | 5 |
| YAS (1:1:1) | | | 10⁻⁶ | |
| 3 | 1500 | 19.2 | 1 × 10⁻⁸ to 1 × | 1 |
| YAS (9:2:9) | | | 10⁻⁹ | |
| CE#1 | 1400, 1600 | 10.8 ± 3.9 | 1 × 10⁻³ to 1 × | 5 |
| | (2 step) | | 10⁻⁴ | |
| CE#2 | 1850 | 6.3 ± 1.9 | 1 × 10⁻¹ to 1 × | 3 |
| | | | 10⁻² | |

^{&}represents one standard deviation within sample population

### Joint Microstructure

To qualitatively analyze the microstructure of the composite glass-ceramic, dry-pressed AlN pellets were formed and then debinded, sintered, and ground/polished under the same conditions as the above AlN ASTM F19 samples. The same respective joining pastes and joining parameters as in the above example were then applied to join the sintered pellets. The sintered pellets were then cross-sectioned and incrementally polished using a polishing wheel and diamond suspension up to 1 μm. The polished samples were then analyzed for microstructure via SEM. The microstructure of joint corresponding to the YAS+10% AlN paste (Example 1) is presented in FIGS. 3 & 4 and shows that there is a uniform and consistent joint layer formed at 1500° C. for 30 mins consisting of 4 distinct phases: a yttria aluminosilicate glass (peripheral 110 and core regions 120), aluminosilicate (mullite) crystals 140, and AlN filler particles 130.

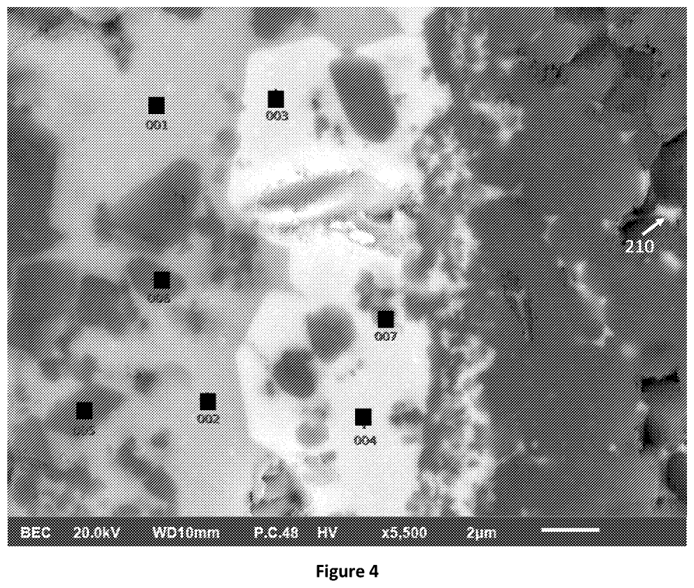

The composition of selected observed phases (FIG. 4) are provided in Table 2, using semi-quantitative EDS analysis. A Y₂O₃ rich phase 210 (light phase) was also identified in the AlN component 100. The peripheral glass phase located 110 at the interface of the AlN components may be at least partially derived from the Y₂O₃ sintering additive in the AlN components 100, 105.

TABLE 2

| Phase (wt %) | Al₂O₃ | SiO₂ | Y₂O₃ |
|---|---|---|---|
| YAS glass (core) #001 | 21 | 35 | 44 |
| YAS glass (core) #002 | 21 | 36 | 43 |
| YAS glass (peripheral) | 36 | 3 | 61 |
| #003 | | | |
| YAS glass (peripheral) | 36 | 3 | 61 |
| #004 | | | |
| Crystalline Al₂O₃ #005 | 85 | 15 | — |
| Crystalline Al₂O₃ #006 | 87 | 13 | — |
| Crystalline Al₂O₃ #007 | 55 | 45 | — |

The % surface area of the YAS glass, mullite and AlN phases was calculated through measuring the relative surface areas of four joint, each having a surface area of about 2000 μm². Buehler OmniMet™ software was used to measure the features on the images, which had been identified as YAS glass, AlN particles and mullite particles, through XRD and EDS analysis. The area measurement tool of the software was used to measure the number of pixels of the AlN and mullite phases. The % surface area of the AlN and mullite phase were determined by comparing the number of pixels relative to the total number of pixels in the joint area being measured. The % wt YAS glass was determined by difference (total−mullite−AlN). For the purposes of the present invention, the proportion of the % surface area of a phase is assumed to equal its wt % proportion (or its volume % proportion). For example, a 10% joint surface area of YAS glass is deemed to equate to 10 wt % of YAS glass in the joint.

The range of the relative portion of the phases is presented in Table 3 from the four joints produced from the paste comprising the abovementioned YAS+10 wt % AlN. For the purposes of the present invention, the % surface area of each of the phases may be regarded as the wt % of each of the phases.

TABLE 3

| phase | YAS glass | Mullite | AlN |
|---|---|---|---|
| % wt | 68-76 | 16-22 | 8-10 |

### Effect of AlN Addition Phases

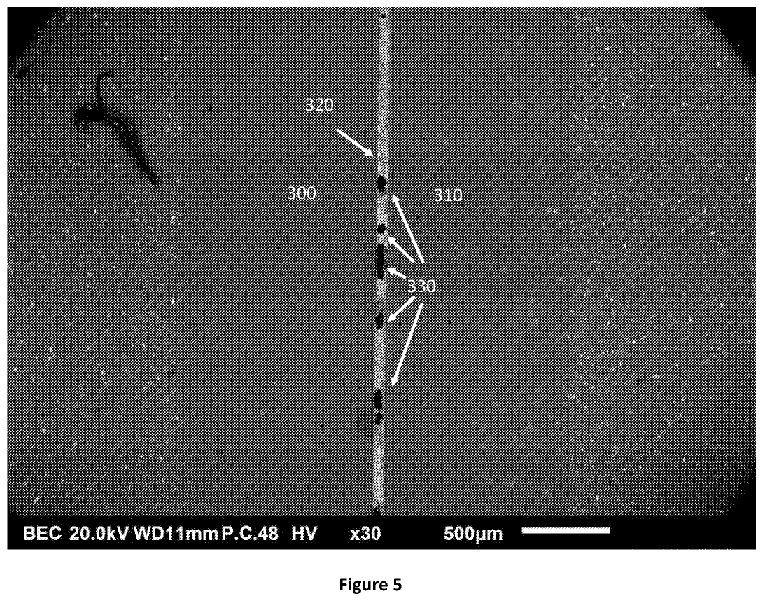

In general, the YAS glass phase should flow and fill in gaps, creating a dense and hermetic seal. However, in Example 2 the joint has a low hermetic value (Table 1). Visually analyzing the joint during its formation, it is observed that there is some overflow of the glass onto the sides of the sample. The resultant joint, as illustrated in FIG. 5 shows a first AlN substrate 300 and a second AlN substrate 310 connected by a joint 320, which comprised a number of voids 330.

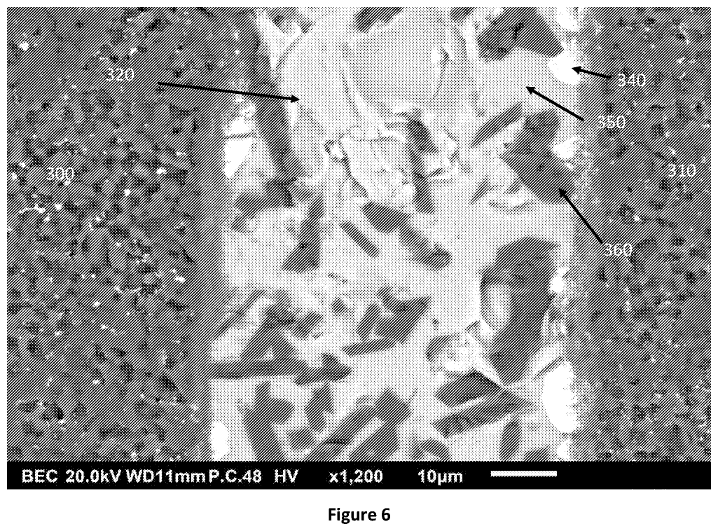

Upon increased magnification (FIG. 6), the joint 320 comprises a peripheral glass phase 340 and a core glass phase 350, although there is a relatively lower proportion of the peripheral glass phase to core glass phase compared to Example 1. The angular darker grains 360 correspond to a crystalline aluminosilicate phase. The peripheral glass phase 340 is located in a peripheral region that interfaces with at least a portion of the first and/or second aluminum nitride substrates 300, 310. The core glass phase 350 is located in at least a central region of the joint. In one or more embodiments, the core glass phase 350 spans from the first aluminum nitride substrate to the second aluminum nitride substrate 300, 310.

While not wanting to be bound by theory, it is thought that, in Example 2, the glass was too fluid at the firing temperature and amounts of molten glass were forced out of the joint substrate interface. This resulted in insufficient reaction between the joint material and substrate at the substrate interface, with the migrated glass phase leaving behind voids at the joint interface. The lower proportion of the peripheral glass phase to the core glass phase may be a reflective of this lower level of reaction.

It is thought that by adding a small amount of AlN powder, there is an increase in glass viscosity at the application temperature, which enables the glass to be contained within the joint region, thereby preventing YAS glass migration away from the joint substrate interface and ensuring a sufficiently dense and hermetic joint. The AlN particles also reduce the differences in the coefficient of thermal expansion across the joint. Without AlN particles, the joint is also more susceptible to thermal shock and, as a result, micro-cracking may occur which provides gaseous pathways through the joint thereby also affecting the hermeticity value over time.

### Effect of Crystalline Aluminosilicate

The effect of crystalline aluminosilicate is illustrated in comparative Example 3 (Table 1), with the absence of this component within the joint resulting in a reduction joint strength by about 20%. The crystalline phase is thought to function as a crack inhibitor, thereby interrupting crack propagation and improving joint strength and fracture toughness.

### Comparative Examples

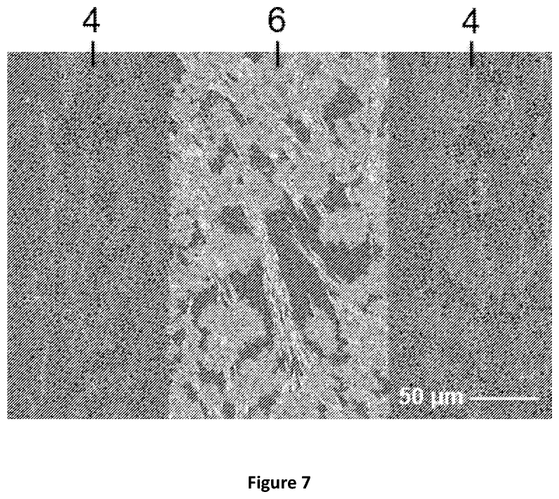

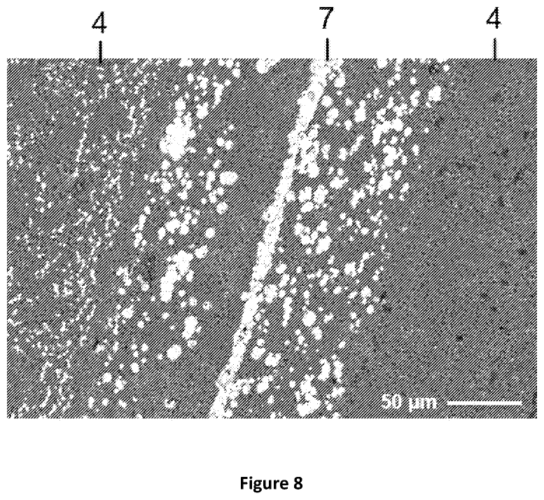

In FIG. 7, the microstructure of the Comparative Example #1 joining material, 6, is shown disposed between sintered AlN bodies, 4, following firing at 1400° C. and 1600° C. for 2 hrs each. FIG. 7 shows evidence of less flow of the CaO-based glass phase, leaving behind a not fully homogenized and uniform joint layer. In FIG. 8, the microstructure of Comparative Example #2 joining material, 7, is shown disposed between sintered AlN substrates, 4, following firing at 1850° C. for 1 hr. FIG. 8 presents a joint layer which has a highly non-uniform joining interface, additionally, the high temperatures required for bonding have significantly affected the distribution of the liquid-phase at the adjacent AlN substrates, which could potentially impact the properties and performance of the base AlN material. Overall, the results in Table 3 and the microstructure analysis indicate that the joints of Examples 1, 2 & 3 of the present disclosure exhibits (relative to CE #1 and CE #2) improved hermeticity and strength. Additionally, the assemblies of the present invention possess good joint homogeneity; uniform distribution and controlled formation of distinct glass and crystalline phases, when present.

Although the foregoing disclosure has been described in detail by way of illustration and example for purposes of clarity and understanding, it will be recognized that the above-described disclosure may be embodied in numerous other specific variations and embodiments without departing from the spirit or essential characteristics of the disclosure. Certain changes and modifications may be practiced, and it is understood that the disclosure is not to be limited by the foregoing details, but rather is to be defined by the scope of the appended claims.

1. An assemblage of a semiconductor processing apparatus comprising a first aluminum nitride (AlN) component and a second aluminum nitride component, wherein the first and second aluminum nitride components are connected by a joint, said joint comprising a composite glass-ceramic comprising:
(a) Y₂O₃—Al₂O₃—SiO₂ (YAS) glass; and
(b) at least one of mullite and aluminum nitride.

2. The assemblage of claim 1 comprising: the Y₂O₃—Al₂O₃—SiO₂ (YAS) glass, the mullite, and the aluminum nitride.

3. The assemblage of claim 1, wherein the at least one of the mullite and/or the aluminum nitride is encompassed by the YAS glass.

4. The assemblage of claim 1, wherein the joint comprises:
50 to 100 wt % Y₂O₃—Al₂O₃—SiO₂ (YAS) glass; and
1 to 30 wt % mullite; and/or 2 to 50 wt % aluminum nitride;

5. The assemblage of claim 1, wherein the YAS glass comprises:
20-70 wt % Y₂O₃;
10-50 wt % Al₂O₃; and
1-50 wt % SiO₂,
wherein the sum of Y₂O₃+Al₂O₃+SiO₂ is at least 95 wt %.

6. The assemblage according to claim 1, wherein the YAS glass comprises a peripheral region and a core region, said peripheral region interfacing with at least a portion of the first and/or second aluminum nitride components and the core region located in at least a central region of the joint.

7. The assemblage according to claim 6, where in the peripheral region comprises a YAS glass composition with an alumina content greater than the YAS glass of the core region.

8. The assemblage according to claim 6, wherein the YAS glass composition of the peripheral region comprises:
45-70 wt % Y₂O₃;
20-50 wt % Al₂O₃; and
1-20 wt % SiO₂,
wherein the sum of Y₂O₃+Al₂O₃+SiO₂ is at least 95 wt %.

9. The assemblage according to claim 6, wherein the YAS glass composition of the core region comprises:
30-55 wt % Y₂O₃;
10-30 wt % Al₂O₃; and
15-50 wt % SiO₂,
wherein the sum of Y₂O₃+Al₂O₃+SiO₂ is at least 95 wt %.

10. The assemblage according to claim 1, wherein the joint comprises 2 to 50 wt % AlN.

11. (canceled)

12. The assemblage of claim 10 or 11, wherein the joint comprises 1 to 30 wt % mullite.

13. The assemblage according to claim 1, wherein the first and/or the second AlN component comprises a Y₂O₃ rich phase comprising at least 30 wt % Y₂O₃.

14.-15. (canceled)

16. The assemblage of claim 1, wherein a thickness of the joint is no more than 150 μm.

17. The assemblage of claim 1, comprising a He leakage rate of no more than 1×10⁻⁷ mbar-l/sec determined in accordance with ASTM F19.

18. The assemblage of claim 1, wherein the first AlN component is an electrostatic chuck and the second AlN component is a pedestal shaft.

19. An assemblage of a semiconductor processing apparatus comprising a first aluminum nitride (AlN) component and a second aluminum nitride component, wherein the first and second aluminum nitride components are connected by a joint, said joint comprising a composite glass-ceramic comprising a Y₂O₃—Al₂O₃—SiO₂ (YAS) glass phase comprising:
20-70 wt % Y₂O₃;
10-50 wt % Al₂O₃; and
1-50 wt % SiO₂,
wherein the sum of Y₂O₃+Al₂O₃+SiO₂ is at least 95 wt %.

20. The assemblage of claim 19, wherein the first and/or the second AlN component comprises in a range of at least 1 to 7 wt % Y₂O₃.

21. The assemblage of claim 19, wherein the joint comprises one or both of 2 to 50 wt % AlN and 1 to 30 wt % mullite.

22.-32. (canceled)

33. A paste for use in forming the assemblage as defined claim 1, comprising a composite glass-ceramic or precursor thereof having a composition comprising, on a solvent free basis:
10-60 wt % Y₂O₃;
5-40 wt % Al₂O₃;
10-60 wt % SiO₂; and
0-30 wt % AlN,
wherein the sum of Y₂O₃+Al₂O₃+SiO₂+AlN is at least 95 wt %.

34. The paste of claim 33, comprising:
20-40 wt % Y₂O₃;
20-40 wt % Al₂O₃;
20-40 wt % SiO₂; and
1-20 wt % AlN.

35. (canceled)
